(19) United States
(12) Patent Application Publication
(10) Pub. No.: US 2020/0294835 A1
(43) Pub. Date: Sep. 17, 2020

(54) METHOD TO IMPROVE NIKON WAFER LOADER REPEATABILITY

(71) Applicant: TEXAS INSTRUMENTS INCORPORATED, Dallas, TX (US)

(72) Inventor: Gao Yong WU, Chengdu (CN)

(21) Appl. No.: 16/550,538

(22) Filed: Aug. 26, 2019

Related U.S. Application Data
(63) Continuation of application No. PCT/CN2019/077778, filed on Mar. 12, 2019.

(51) Int. Cl. H01L 21/68; H01L 21/67; G03F 9/00; G03F 7/00

(52) U.S. Cl. CPC H01L 21/68; H01L 21/67259; H01L 2223/54453; G03F 7/0035; G03F 9/708; G03F 9/7084

(57) ABSTRACT

A microelectronic device is formed by loading a wafer, in which the microelectronic device is being formed, onto a pre-alignment stage for a wafer stepper. If the pre-alignment stage does not align the wafer properly using a notch pin, the wafer is loaded onto a wafer stepper stage of the wafer stepper. The wafer is positioned under a Field Image Alignment (FIA) camera of the wafer stepper, so that the FIA camera provides an image of the wafer notch. The wafer is rotated into a proper position. The wafer is transferred back to the pre-alignment stage. The wafer is aligned using the notch pin. The wafer is transferred to the wafer stepper stage. Fabrication is continued to form the microelectronic device.

### FIELD

This disclosure relates to the field of microelectronic devices. More particularly, this disclosure relates to photolithographic processes used in forming microelectronic devices.

### BACKGROUND

During fabrication of integrated circuits, wafers are coated with photoresist and exposed in photolithographic exposure tools, commonly referred to as wafer steppers. Before being loaded into the wafer steppers, the wafers are pre-aligned on a pre-alignment stage using a notch pin to engage the notch in the wafer. Occasionally, a wafer is loaded onto the pre-alignment stage out of position, so that the wafer cannot be properly aligned by the notch pin. Rectifying this problem is costly in terms of manpower and throughput through the wafer stepper.

### SUMMARY

The present disclosure introduces a method for forming a microelectronic device. A wafer, in which the microelectronic device is being formed, is loaded onto a pre-alignment stage having a notch pin. If the pre-alignment stage does not align the wafer properly, the wafer is loaded onto a wafer stepper stage of a wafer stepper. The wafer is positioned under a Field Image Alignment (FIA) camera of the wafer stepper, so that the FIA camera provides an image of the wafer notch. The wafer is rotated into a proper position using the error estimate. The wafer is transferred back to the pre-alignment stage. The wafer is aligned using the notch pin. The wafer is transferred to the wafer stepper stage. Fabrication is continued to form the microelectronic device.

### BRIEF DESCRIPTION OF THE VIEWS OF THE DRAWINGS

FIG. 1 is a flowchart of an example method of forming the microelectronic device.

FIG. 2A shows an example pre alignment stage used in a Nikon i11 stepper or a Nikon i12 stepper.

FIG. 2B depicts a wafer table with a wafer disposed on a wafer holder.

FIG. 2C depicts a notch pin and a wafer notch in more detail.

FIG. 3 depicts a Nikon i11/i12 wafer stepper with a wafer stepper stage, and a wafer disposed on the wafer stepper stage.

FIG. 4 depicts a rotational adjustment joystick of the Nikon i11/i12 wafer stepper.

FIG. 5A depicts an example of a fabrication step using the patterned photoresist layer.

FIG. 5B depicts another example of a fabrication step using the patterned photoresist layer.

FIG. 5C depicts the completed microelectronic device.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A microelectronic device is formed by a process which includes a photolithographic operation. The microelectronic device may be manifested as an integrated circuit, a semiconductor device, an electro-optical device, a microelectromechanical system (MEMS) device, or a microfluidics device, for example. The microelectronic device being formed is contained in a wafer, which may be implemented as a semiconductor wafer, a silicon-on-insulator (SOI) wafer, a silicon carbide or sapphire wafer, or other suitable wafer appropriate for the microelectronic device. By way of example, the photolithographic operation may be implemented to form an etch mask or an implant mask.

It is noted that the terms “over” and “under” are used in this disclosure. These terms should not be construed as limiting the position or orientation of a structure or element, but should be used to provide spatial relationship between structures or elements.

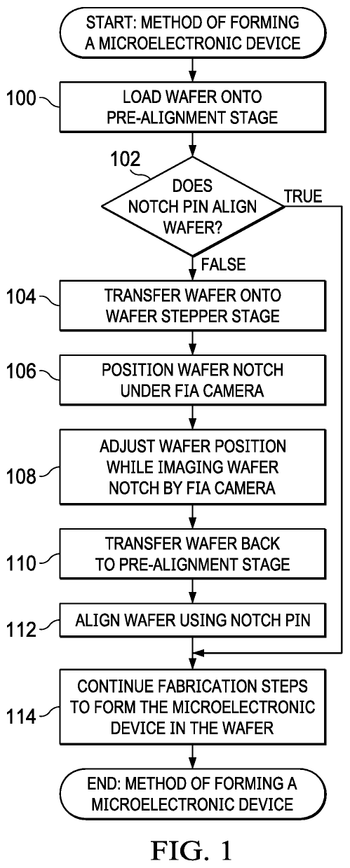

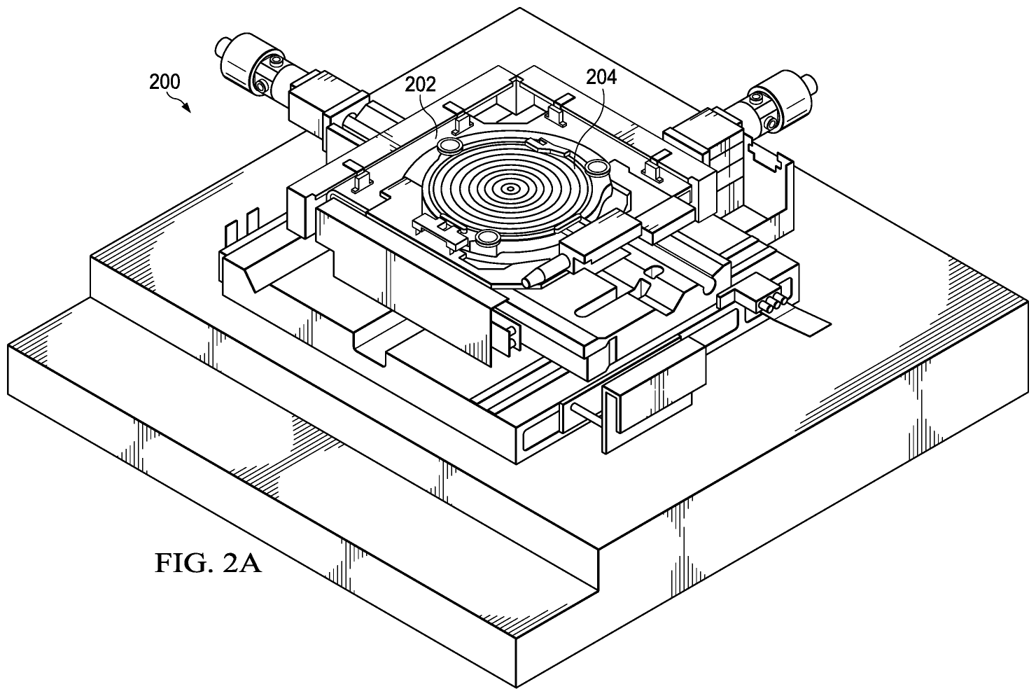

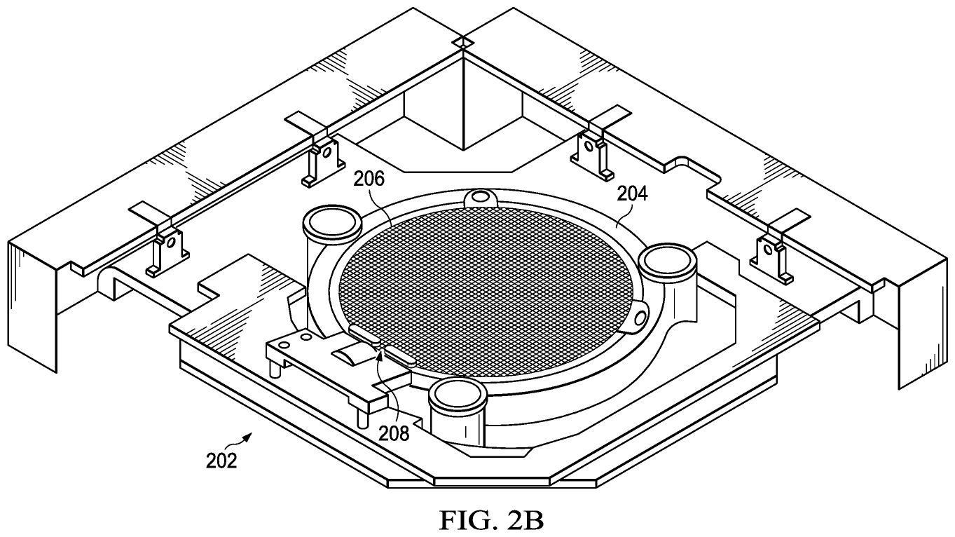

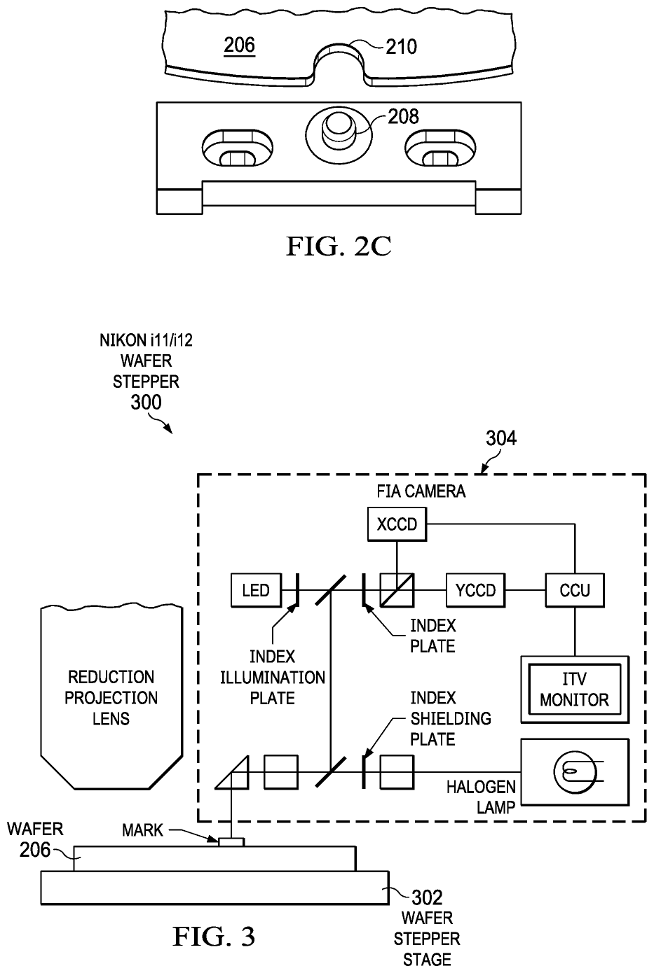

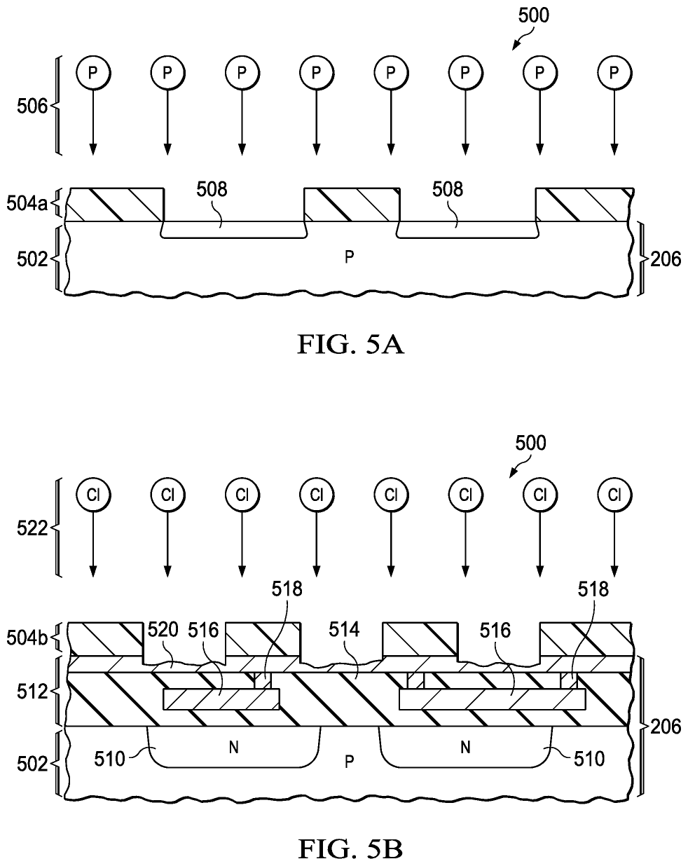

FIG. 1 is a flowchart of an example method of forming the microelectronic device 500, shown in FIG. 5C. Referring back to FIG. 1, the method starts with step 100, which is to load the wafer onto a pre-alignment stage of a photolithographic exposure tool, referred to herein as the wafer stepper. FIG. 2A shows an example pre-alignment stage 200 used in a Nikon i11 stepper or a Nikon i12 stepper, referred to herein as a Nikon i11/i12 wafer stepper. The pre-alignment stage 200 includes a wafer table 202 which is configured to rotate a wafer holder 204. FIG. 2B depicts the wafer table 202 with a wafer 206 disposed on the wafer holder 204. The wafer table 202 includes a notch pin 208 adjacent to a wafer notch in the wafer 206. FIG. 2C depicts the notch pin 208 and the wafer notch 210 in more detail. After the wafer 206 is loaded onto the pre-alignment stage 200, the notch pin 208 is moved toward the wafer notch 210 in an attempt to engage the wafer notch 210 with the notch pin 208 and align the wafer 206.

Referring back to FIG. 1, the method of forming the microelectronic device 500 continues with step 102, which is to determine if the notch pin 208 aligns the wafer 206 properly. If the notch pin 208 does not align the wafer 206 properly, that is, the result of step 102 is FALSE, the method continues with step 104. If the notch pin 208 does align the wafer 206 properly, that is, the result of step 102 is TRUE, the method continues with step 114.

Step 104 is to transfer the wafer 206 to a wafer stepper stage 302 of a wafer stepper 300, shown in FIG. 3. FIG. 3 depicts a Nikon i11/i12 wafer stepper 300 with the wafer stepper stage 302, and the wafer 206 disposed on the wafer stepper stage 302.

Referring back to FIG. 1, the method of forming the microelectronic device 500 continues with step 106, which is to position the wafer notch 210 of FIG. 2C under a Field Image Alignment (FIA) camera 304, shown in FIG. 3. The FIA camera 304 is also used to determine positions of alignment marks on the wafer 206. In this method of forming the microelectronic device, the wafer 206 is positioned so that the wafer notch 210 is displayed in an image provided by the FIA camera 304.

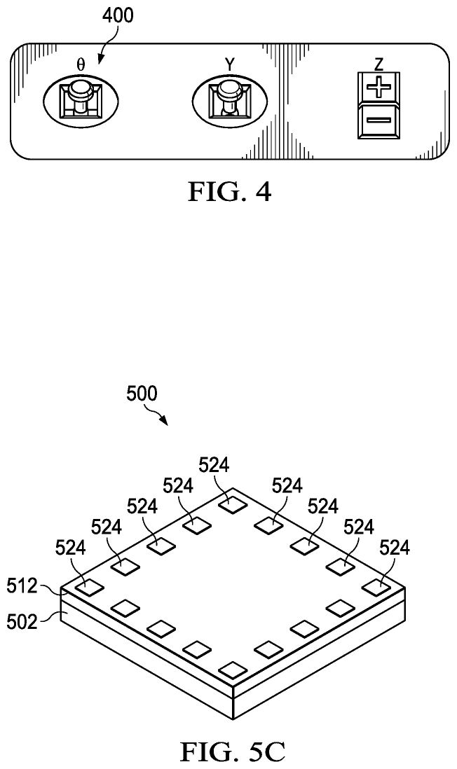

Referring back to FIG. 1, the method of forming the microelectronic device 500 continues with step 108, which is to adjust a position of the wafer 206 on the pre-alignment stage 200 using images provided by the FIA camera 304. The position of the wafer 206 may be adjusted by rotating the wafer holder 204 of the wafer table 202 of the pre-alignment stage 200. The position of the wafer 206 is adjusted so that the wafer 206 may be subsequently aligned on the pre-alignment stage 200 by engaging the notch pin 208 in the wafer notch 210. FIG. 4 depicts a rotational adjustment joystick 400 of the Nikon i11/i12 wafer stepper. The rotational adjustment joystick 400 is labeled “θ” in FIG. 4, to indicate the rotational adjustment joystick 400 provides rotational movement of the wafer holder 204.

Referring back to FIG. 1, the method of forming the microelectronic device 500 continues with step 110, which is to transfer the wafer 206 from the wafer stepper stage 302 to the pre-alignment stage 200.

The method of forming the microelectronic device 500 continues with step 112, which is to align the wafer 206 by engaging the notch pin 208 in the wafer notch 210 on the pre-alignment stage 200. Adjusting the position of the wafer 206 as disclosed in step 108 may advantageously enable successful alignment of the wafer 206 using the notch pin 208.

The method of forming the microelectronic device 500 continues with step 114, which is to continue fabrication steps to form the microelectronic device 500. The wafer stepper 300 exposes photoresist on the wafer 206 to ultraviolet light in a pattern defined by a photomask used in the wafer stepper 300. The photoresist is subsequently developed to provide a patterned photoresist layer.

FIG. 5A depicts an example of a fabrication step using the patterned photoresist layer. The microelectronic device 500 has a substrate 502 of a semiconductor material, such as p-type silicon, the substrate being a part of the wafer 206. In this example step, a first implementation of the patterned photoresist layer 504a provides an implant mask. Dopant ions 506, implemented as phosphorus ions 506 in this example, are implanted into the substrate 502 where exposed by the patterned photoresist layer 504a to form implanted regions 508 in the substrate 502. The patterned photoresist layer 504a is subsequently removed, and the substrate 502 is heated to activate the implanted phosphorus ions in the implanted regions 508 to form n-type regions.

FIG. 5B depicts another example of a fabrication step using the patterned photoresist layer. The microelectronic device 500 includes the substrate 502 with n-type wells 510 formed as described in reference to FIG. 5A. The microelectronic device 500 further includes an interconnect region 512 over the substrate 502. The interconnect region 512 includes dielectric material 514, implemented as dielectric layers of silicon dioxide, silicon nitride, phosphosilicate glass (PSG), borophosphosilicate glass (BPSG), organosilicate glass (OSG), or other dielectric thin film materials. The interconnect region 512 includes interconnects 516 of aluminum, and vias 518 of tungsten. An aluminum layer 520 is formed in the interconnect region 512. In this example, a second implementation of the patterned photoresist layer 504b is formed over the aluminum layer 520 to define areas for additional interconnects. A reactive ion etch (ME) process using chlorine ions 522 is used to remove the aluminum layer 520 where exposed by the patterned photoresist layer 504b. FIG. 5B depicts the RIE process partway to completion. After the ME process is completed, the patterned photoresist layer 504b is removed.

FIG. 5C depicts the completed microelectronic device 500. The microelectronic device 500 includes the substrate 502, and the interconnect region 512 over the substrate 502. The microelectronic device 500 may include input/output (I/O) terminals 524. The I/O terminals 524 may be manifested, for example, as wire bond pads or solder bump pads. The I/O terminals 524 may be located in the interconnect region 512, as depicted in FIG. 5C. Alternatively, the I/O terminals 524 may be located under the substrate 502, opposite from the interconnect region 512, using through-substrate vias (TSVs). The microelectronic device 500 is singulated from the wafer 206 of FIG. 3, to provide the completed microelectronic device 500.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A method of forming a microelectronic device, comprising:
loading a wafer onto a pre-alignment stage for a wafer stepper, the wafer having a wafer notch, the pre-alignment stage having a notch pin;
transferring the wafer to a wafer stepper stage of the wafer stepper;
positioning the wafer notch under a Field Image Alignment (FIA) camera of the wafer stepper, the FIA camera providing an image of the wafer notch;
adjusting a position of the wafer while the FIA camera provides the image of the wafer notch;
transferring the wafer back to the pre-alignment stage;
aligning the wafer using the notch pin; and
exposing a photoresist layer on the wafer to ultraviolet light through a photomask.

2. The method of claim 1, wherein the wafer stepper is selected from the group consisting of a Nikon i11 wafer stepper and a Nikon i12 wafer stepper.

3. The method of claim 1, wherein adjusting the position of the wafer is performed using a rotational adjustment joystick of the wafer stepper.

4. The method of claim 1, further comprising:
exposing photoresist on the wafer using the wafer stepper;
developing the photoresist to provide a patterned photoresist layer;
implanting dopant ions into a substrate of the microelectronic device where exposed by the patterned photoresist layer, the substrate being a part of the wafer; and
subsequently removing the patterned photoresist layer.

5. The method of claim 1, further comprising:
exposing photoresist on the wafer using the wafer stepper;
developing the photoresist to provide a patterned photoresist layer over a layer on the wafer;
removing material from the layer where exposed by the patterned photoresist layer; and
subsequently removing the patterned photoresist layer.

6. The method of claim 1, wherein the transferring the wafer to the wafer stepper stage is conditional on the notch pin failing to align the wafer.
